(19) United States
(12) Patent Application Publication
(10) Pub. No.: US 2005/0145914 A1
(43) Pub. Date: Jul. 7, 2005

(54) Semiconductor device having trench capacitor and fabrication method for the same

(75) Inventors: Toshiharu Tanaka, Yokohama-shi (JP); Hideaki Aochi, Kawasaki-shi (JP); Masaru Kito, Yokohama-shi (JP); Masaru Kido, Kawasaki-shi (JP)

Correspondence Address: BANNER & WITCOFF, 1001 G STREET N W, SUITE 1100, WASHINGTON, DC, 20001, US

(73) Assignee: Kabushiki Kaisha Toshiba, Minato-ku (JP)

(21) Appl. No.: 10/892,496

(22) Filed: Jul. 16, 2004

(30) Foreign Application Priority Data
Jan. 7, 2004 (JP) P2004-2061

(51) Int. Cl. H01L 21/8242; H01L 27/108; H01L 29/76; H01L 21/20

(52) U.S. Cl. 257/301; 438/243; 438/386

(57) ABSTRACT

A semiconductor memory includes a semiconductor substrate; a capacitor arranged in a lower portion of the trench; a collar oxide film arranged on a side of the trench above the capacitor and having an upper collar member and a lower collar member, the upper collar member being thinner than the lower collar member so as to provide a height difference therebetween; a storage node arranged on a side of the collar oxide film; a select transistor provided on the semiconductor substrate and having a doped layer in contact with the collar oxide film; and a conductor portion arranged upon the storage node and the doped layer.

### CROSS REFERENCE TO RELATED APPLICATIONS

This application is based upon and claims the benefit of priority from prior Japanese Patent Applications No. P2004-2061, filed on Jan. 7, 2004; the entire contents of which are incorporated herein by reference.

### BACKGROUND OF THE INVENTION

1. Field of the Invention

The present invention relates to a semiconductor memory device having capacitors in trenches in a semiconductor substrate. Particularly, the invention relates to a surface strap contact, which connects a storage node and a doped layer of a select transistor for conduction.

2. Description of the Related Art

There are semiconductor memory devices may have capacitors provided in trenches in a semiconductor substrate. The capacitors are connected to select transistors, and charges accumulated in the capacitors can be controlled by turning the select transistors on and off. More specifically, doped layers of the select transistors and storage nodes connected to storage electrodes of the capacitors are electrically connected by surface strap contacts. The surface strap contacts are provided on the surface of the semiconductor substrate and not in the trenches.

To the contrary, the doped layers and the storage nodes of the select transistor are insulated by collar oxide films below the surface of the semiconductor substrate. The collar oxide film serves as a gate insulator film for a parasitic transistor provided between the select transistor and a plate electrode of the capacitor. Increasing the threshold voltage of the parasitic transistor and the thickness of the collar oxide film is necessary in order to prevent the parasitic transistor from being turned on. However, the doped layers and the storage nodes of the select transistor are separated by just the thickness of the collar oxide film even at the surface of the semiconductor substrate.

A method of forming collar oxide films differing in thickness along the depth is proposed.

### SUMMARY OF THE INVENTION

A first aspect of the present invention inheres in semiconductor memory including a semiconductor substrate having a trench; a capacitor having a storage electrode and arranged in a lower portion of the trench; a collar oxide film arranged on a side of the trench above the capacitor and having an upper collar member and a lower collar member, the upper collar member being thinner than a thickness of the lower collar member so as to provide a height difference therebetween; a storage node arranged on a side of the collar oxide film in an upper portion of the trench and electrically connected to the storage electrode; a select transistor provided on a surface of the semiconductor substrate and having a doped layer in contact with the collar oxide film; and a conductor portion arranged upon the storage node and the doped layer opposing each other via the collar oxide film.

A second aspect of the present invention inheres in a method of fabricating a semiconductor memory including forming a trench in a semiconductor substrate; forming a capacitor having a storage electrode, in a lower portion of the trench; forming a collar oxide film having an upper collar member and a lower collar member, the upper collar member being thinner than a thickness of the lower collar member so as to provide a height difference therebetween, on a side of the trench; forming a storage node, which is electrically connected to the storage electrode, on a side of the collar oxide film in an upper portion of the trench; forming a select transistor having a doped layer in contact with the collar oxide film and provided on a surface of the semiconductor substrate; and forming a conductor portion arranged upon the storage node and the doped layer opposing each other via the collar oxide film.

### BRIEF DESCRIPTION OF THE DRAWINGS

FIG. 1 is a top view of a semiconductor memory according to a first embodiment;

FIG. 2 is a cross-sectional diagram cut along the line II-II of FIG. 1;

FIG. 3 is an enlarged view of a part of the cross-sectional diagram of FIG. 2;

FIGS. 4 through 8 are cross-sectional diagrams of the semiconductor memory according to the first embodiment in the course of fabrication;

FIG. 9 is a cross-sectional diagram of a semiconductor memory according to a second embodiment;

FIGS. 10 through 13 are cross-sectional diagrams of the semiconductor memory according to the second embodiment in the course of fabrication;

FIGS. 14 through 15 are cross-sectional diagrams of a semiconductor memory according to a third embodiment in the course of fabrication;

FIG. 16 is a cross-sectional diagram of a semiconductor memory according to a fourth embodiment; and

FIGS. 17 through 22 are cross-sectional diagrams of the semiconductor memory according to the fourth embodiment in the course of fabrication.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

(Semiconductor Memory)

It is desirable to increase in memory capacity of a semiconductor memory. In order to increase the memory capacity, the integration density of select transistors should be increased. In order to increase the integration density, the select transistors must be smaller, and intervals therebetween must be narrower. This means that the contact areas between surface strap contacts and doped layers of the select transistors become smaller. Similarly, it also means that the contact areas between the surface strap contacts and storage nodes become smaller. In addition, contact resistance between the surface strap contacts and the doped layers of the select transistors, and contact resistance between the surface strap contacts and the storage nodes increase. Thus the resistance at the surface strap contacts is assumed to increase and an increase in resistance decreases the operating speed of the semiconductor memory.

### FIRST EMBODIMENT

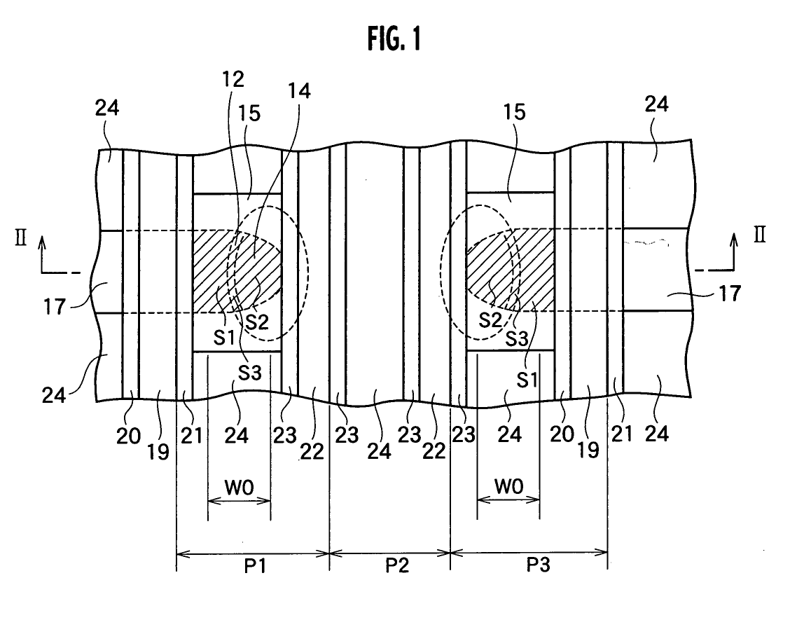

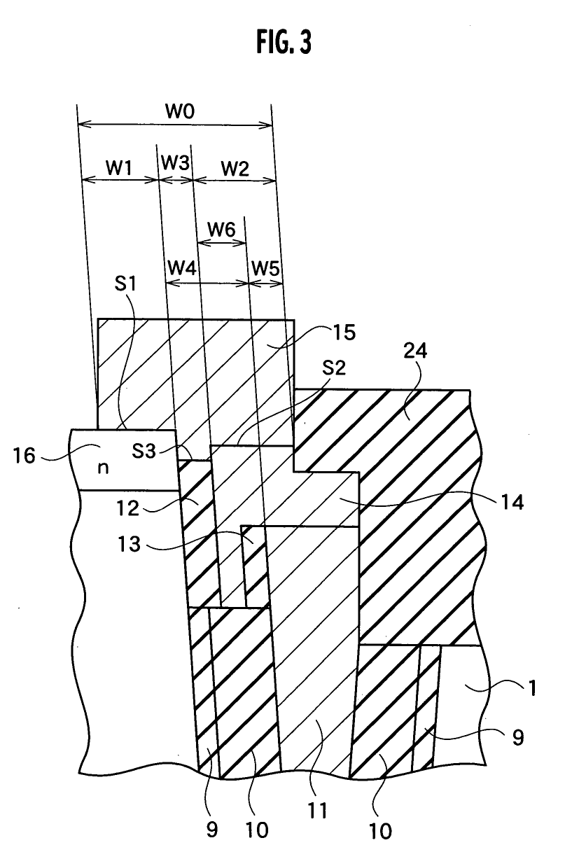

As shown in FIGS. 1 through 3, a semiconductor memory according to a first embodiment of the present invention includes a semiconductor substrate 1, capacitors 28, collar oxide films 9, 10, and 12, storage nodes 14, select transistors 16-21, conductor portions 15, amorphous silicon portions 11, sidewall silicon oxide films 13, a shallow trench isolation (STI) 24, gate interconnects 22, cap insulator films 27, and sidewalls 23.

The semiconductor substrate 1 is provided with trenches. The capacitor 28 is arranged in the lower portion of the trench. The capacitor 28 includes a storage electrode 8, a plate electrode 6, and a capacitor dielectric film 7. The storage electrode 8 is arranged in the lower portion of the trench. The plate electrode 6 is arranged in the semiconductor substrate 1 including the trench surface. The capacitor dielectric film 7 is arranged between the plate electrode 6 and the storage electrode 8 on the trench side.

The collar oxide films 9, 10, and 12 are arranged on the sides of the trench upon the capacitors 28. The collar oxide films 9, 10, and 12 have an upper collar member and a lower collar member. The collar oxide films 9, 10, and 12 have a height difference so that an upper film thickness W3 of the upper collar member is thinner than a lower film thickness W4 of the lower collar member. The collar oxide films 9 and 10 compose thick collar oxide film (9, 10). The collar oxide film 12 is called a thin collar oxide film 12. The thick collar oxide film 9, 10 is arranged on the trench side upon the capacitor 28. The thickness of the thick collar oxide film 9, 10 is equivalent to the lower film thickness W4. The thin collar oxide film 12 is arranged on the trench side upon the thick collar oxide film 9, 10. The thickness of the thin collar oxide film 12 is equivalent to the upper film thickness W3. The top of the thick collar oxide films 9 and 10 is lower in height than that of the amorphous silicon portions 11. The collar oxide film 9 is made of a thermally-oxidized film. The collar oxide film 10 is made of a deposited silicon oxide film. The thermally-oxidized film 9 is arranged on the trench side. The deposited silicon oxide film 10 is arranged on the surface of the thermally-oxidized film 9.

The storage node 14 is arranged on the sides of the collar oxide films 10 and 12 in the upper portion of the trench, respectively. The storage nodes 14 are electrically connected to the storage electrodes 8.

The select transistor has doped layers 16 and 17, a gate insulator film 18, a gate electrode 19, a cap insulator film 26, and sidewalls 20 and 21. The doped layer 16 is provided on the surface of the semiconductor substrate 1, and is in contact with the collar oxide films 10 and 12. The doped layer 17 is provided on the surface of the semiconductor substrate 1, and separated from the doped layer 16. The gate insulator film 18 is provided upon the doped layers 16 and 17 in the semiconductor substrate 1. The gate electrode 19 is arranged upon the gate insulator film 18. The cap insulator film 26 is arranged upon the gate electrode 19. The sidewalls 20 and 21 are arranged on a side of the gate electrode 19 on the gate insulator films 18, respectively.

The conductor portions 15 serve as surface strap contacts. The conductor portions 15 are arranged upon opposing doped layers 16 and storage nodes 14 via the collar oxide films 10 and 12, respectively.

The amorphous silicon portions 11 are arranged in the trenches on the surfaces of the thick collar oxide films 9 and 10. The amorphous silicon portions 11 provide a conduction connection between the storage electrodes 8 and the storage nodes 14.

The sidewall silicon oxide films 13 are arranged on the sides of the amorphous silicon portions 11 above the thick collar oxide films 9 and 10. The STI 24 is arranged in the periphery of the doped layers 16 and 17 of the select transistors 16 through 21 and on the trenches. The gate electrodes 22 are arranged upon the STI 24. The sidewalls 23 are arranged on the sides of the gate interconnects 22 upon the STI 24.

The semiconductor memory of the first embodiment includes the gate electrodes 19 and the gate interconnects 22, and for miniaturization of the semiconductor memory, pitches P1 through P3 of the gate electrodes 19 and the gate interconnects 22 are shortened. For shortening the pitches P1 through P3, the width W0 of the conductor portion 15 is shortened. Even if the width W0 is shortened, a contact area S3 between each collar oxide film 12 and corresponding conductor portion 15 has to be reduced to prevent reduction of a contact area Si between each doped layer 16 and corresponding conductor portion 15, and a contact area S2 between each storage node 14 and corresponding conductor portion 15. Specifically, the thickness W3 of the collar oxide film 12 is made thinner to prevent from reducing the width W1 of the contact surface between each doped layer 16 and corresponding conductor portion 15, and the width W2 of the contact surface between each storage node 14 and corresponding conductor portion 15.

Conventionally, collar oxide films are arranged with a constant film thickness W4 on the trench side extending from the capacitor top end to the trench top. The width of the contact surface between each storage node 14 and corresponding conductor portion 15 becomes as short as width W5. With the semiconductor memory of the first embodiment, the width of the contact surface between each storage node 14 and corresponding conductor portion 15 may be widened to width W2, increasing from the width W5 by only the width W6.

With the first embodiment, only the thin collar oxide films 12 of the upper collar oxide films 9, 10 and 12 are provided as thin films. This allows an increase in the contact surface between each storage node 14 and corresponding conductor portion 15, and a decrease in resistance of the contact interface between each storage node 14 and corresponding conductor portion 15. To the contrary, even if the semiconductor memory is miniaturized, the contact area between each storage node 14 and corresponding conductor portion 15 is not reduced, by making the thin collar oxide film 12 be thinner.

A semiconductor memory fabrication method of the first embodiment is described forthwith.

To begin with, a p-type silicon substrate is prepared as the semiconductor substrate 1. A 2 nm-thick pad silicon oxide film (SiO₂) 2 is formed upon the silicon substrate 1 by oxidizing the substrate 1 through thermal oxidation. A 220 nm-thick pad silicon nitride film (Si₃N₄) is deposited upon the pad silicon oxide film 2 through chemical vapor deposition (CVD). Trenches 4 and 5 are formed in the silicon substrate 1 using photolithography and dry etching techniques.

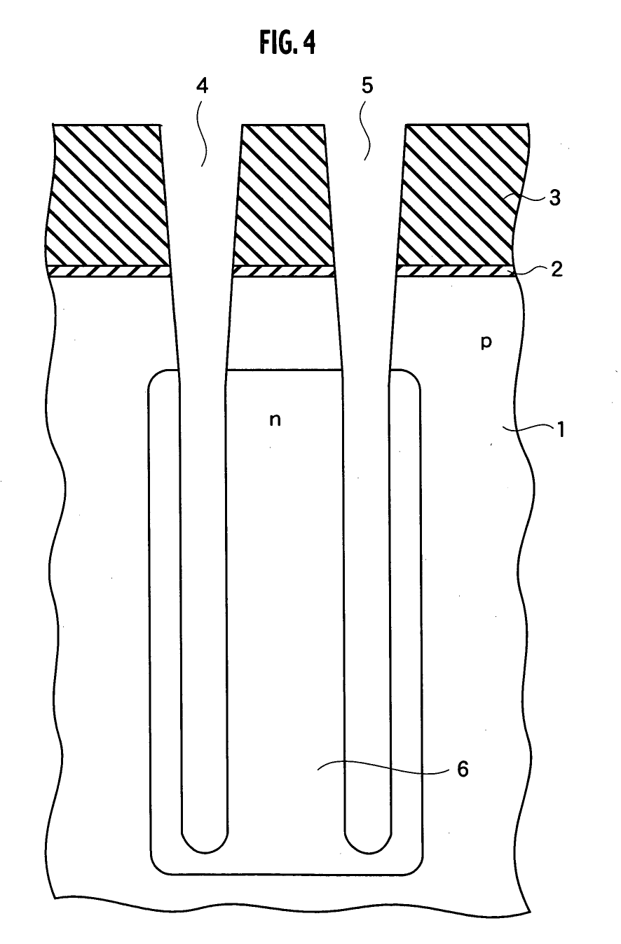

As shown in FIG. 4, an n-type impurity is diffused in regions of the trenches 4 and 5 deeper than 1.5″ m from the surface of the silicon substrate 1. Note that ‘depth’ referred to hereafter means a depth from the surface of the silicon substrate 1. Activating the diffused n-type impurity forms the plate electrode 6. Capacitor dielectric films 7 of 2-3 nm thickness are deposited on the sides of the trenches 4 and 5 through CVD. Phosphorous-doped amorphous silicon films, which become the storage electrodes 8, are deposited through CVD, embedding amorphous silicon columns in the trenches 4 and 5. The amorphous silicon columns are etched back to an appropriate depth of approximately 1.0″ m. This operation forms the capacitors 28.

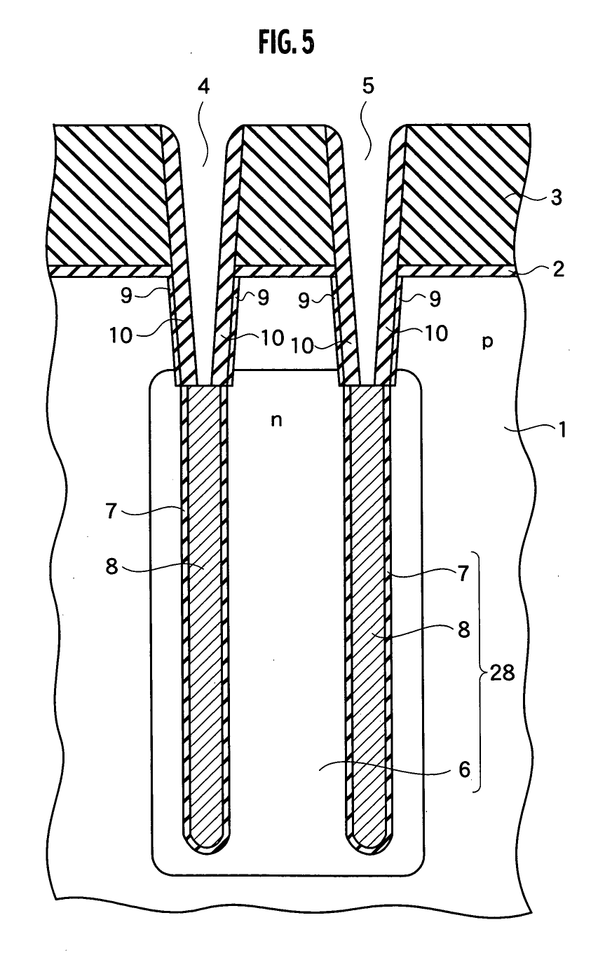

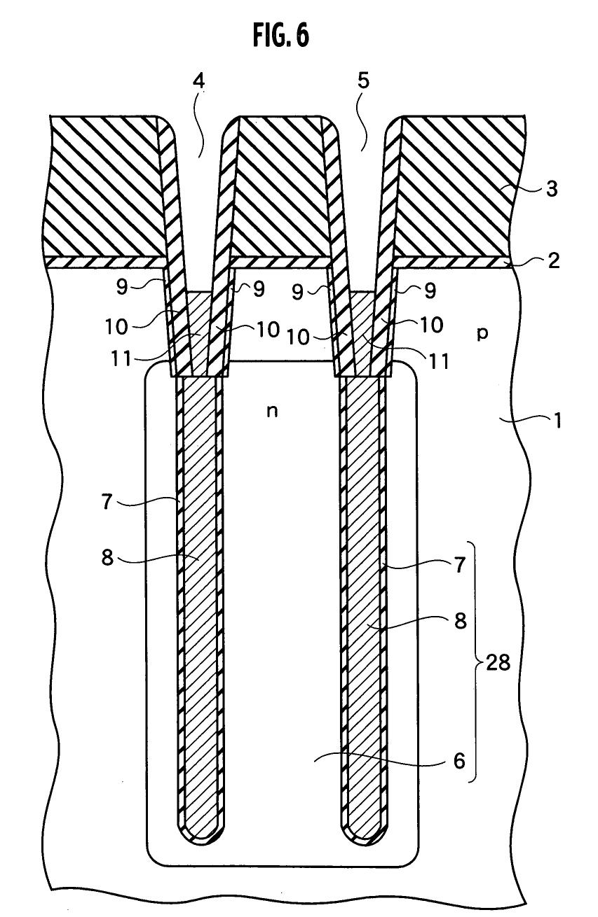

Thermal silicon oxide films 9 of 6 nm thickness are formed on the sides of the trenches 4 and 5 in the silicon substrate 1. A 30 nm-thick silicon oxide film 10 is deposited on the sides of the trenches 4 and 5. This forms the thick collar oxide films 9 and 10. As shown in FIG. 5, the deposited silicon oxide films 10 only on the bottom of the trenches 4 and 5 are removed using dry etching techniques. Phosphorous-doped amorphous silicon films are deposited in the trenches 4 and 5, embedding amorphous silicon portions 11. As shown in FIG. 6, the amorphous silicon portions 11 are etched back to an appropriate depth of at least approximately 150 nm.

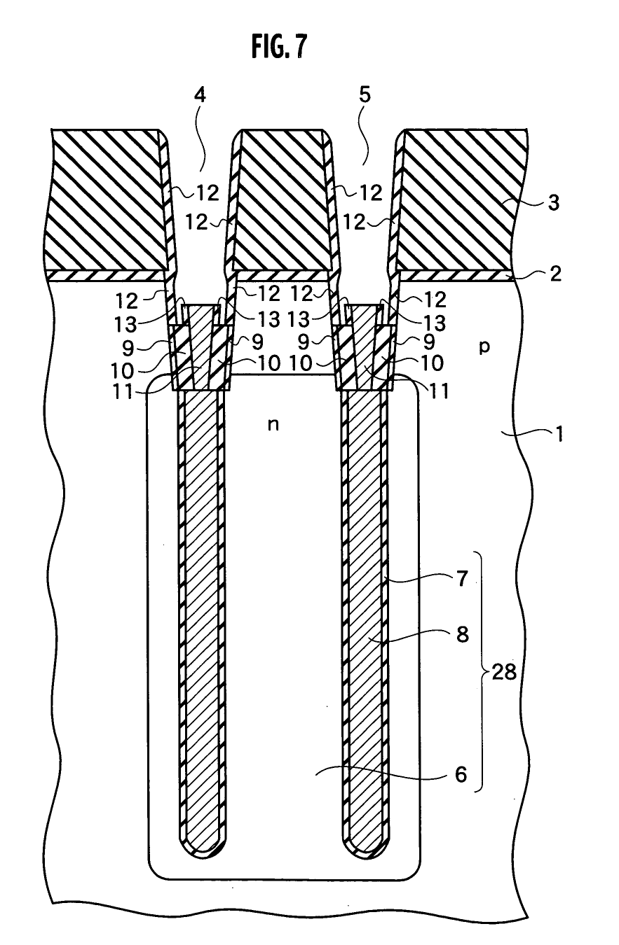

Next, the thick collar oxide films 9 and 10 on the sides of the trenches 4 and 5 are removed through wet etching using the amorphous silicon portions 11 as a mask. Since over etching is required for removal of the thick collar oxide films 9 and 10 on the sides of the trenches 4 and 5, the tops of the thick collar oxide films 9 and 10 become lower than the height of the tops of the amorphous silicon portions 11. Thin silicon oxide films 12 are deposited on the exposed sides of the trenches 4 and 5 through CVD. The thickness of the thin collar oxide films 12 is, for example, 15 nm, and needs to be thinner than the 30 nm-thick deposited silicon oxide films. Furthermore, since leakage current should not be generated between the storage nodes 14, which sandwich the thin collar oxide films 12, and the silicon substrate 1, the thin collar oxide films 12 should be at least 3 nm, more preferably 5 nm or greater. As shown in FIG. 7, the thin collar oxide films 12 only on the bottom of the trenches 4 and 5 are then removed using dry etching techniques. This forms the collar oxide films 9, 10, and 12, which have differences in height so that the upper film thickness W3 is thinner than the lower film thickness W4. Note that the sidewall silicon oxide films 13 are formed on the upper portions of the sides of the amorphous silicon portions 11.

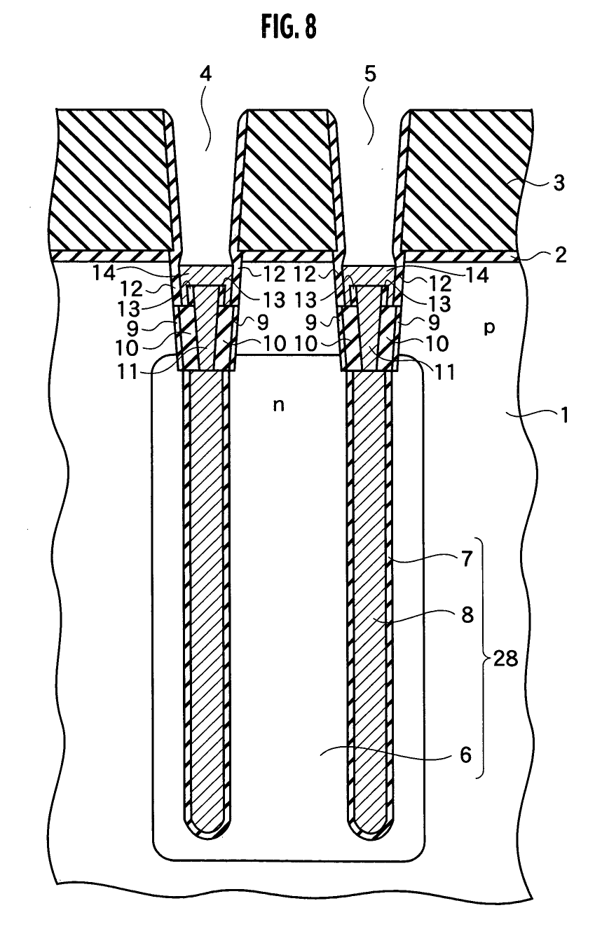

A phosphorous-doped amorphous silicon film is deposited in the trenches 4 and 5, embedding the storage nodes 14. As shown in FIG. 8, the storage nodes 14 are etched back to a necessary depth. This forms the storage nodes 14.

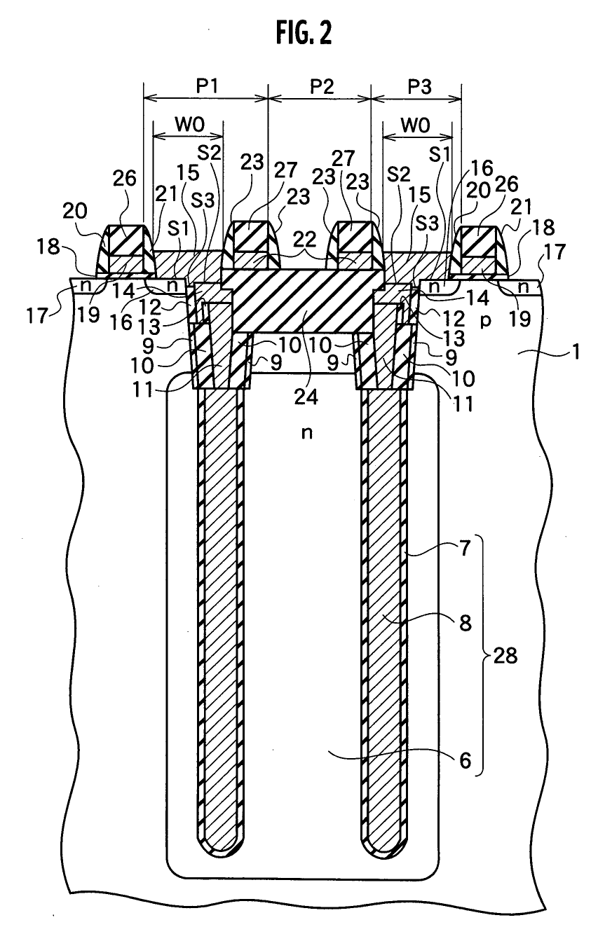

Subsequently, an STI and a trench top oxide (TTO) 24 are formed, establishing active areas for the select transistors 16 through 21 and the select transistors 16 through 21, the gate interconnects 22, and the sidewalls 23 are formed. The thin TTO 24 in the upper portion of the trenches 4 and 5 is etched. As shown in FIGS. 1 and 2, a phosphorous—(P) doped amorphous silicon film is deposited upon the doped layers 16 and the storage nodes 14, forming the conductor portions 15. This allows formation of the surface strap contacts.

As described above, according to the first embodiment, a semiconductor memory, which allows narrow intervals between select transistors without increasing the resistance between surface strap contacts, can be provided. Further according to the first embodiment, a fabrication method for the semiconductor memory, which allows narrow intervals between select transistors without increasing the resistance between surface strap contacts, can be provided.

### SECOND EMBODIMENT

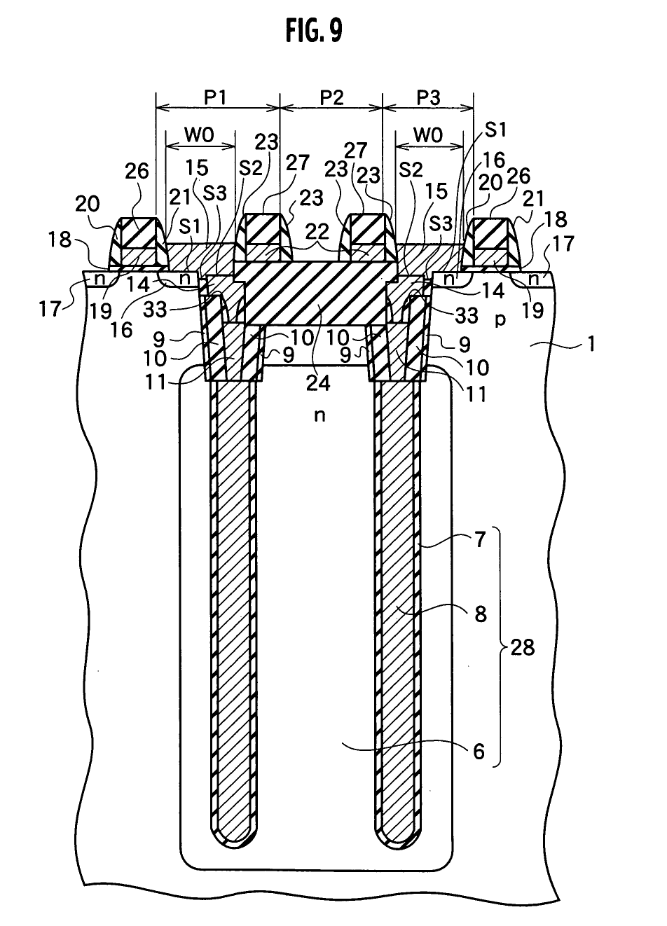

Compared to the semiconductor memory of the first embodiment in FIG. 2, a semiconductor memory according to a second embodiment of the present invention, as shown in FIG. 9, has the tops of the thick collar oxide films 9 and 10 higher than those of the amorphous silicon portions 11. Furthermore, sidewall silicon oxide films 33 are provided, in place of the silicon oxide films 13, on the amorphous silicon portions 11 on the sides of the thick collar oxide films 9 and 10. This allows the same effectiveness as with the first embodiment.

A semiconductor memory fabrication method according to the second embodiment is described. The semiconductor memory fabrication method according to the second embodiment is the same as the semiconductor memory fabrication method according to the first embodiment up until removing the deposited silicon oxide films 10 only on the bottom of the trenches 4 and 5 of FIG. 5.

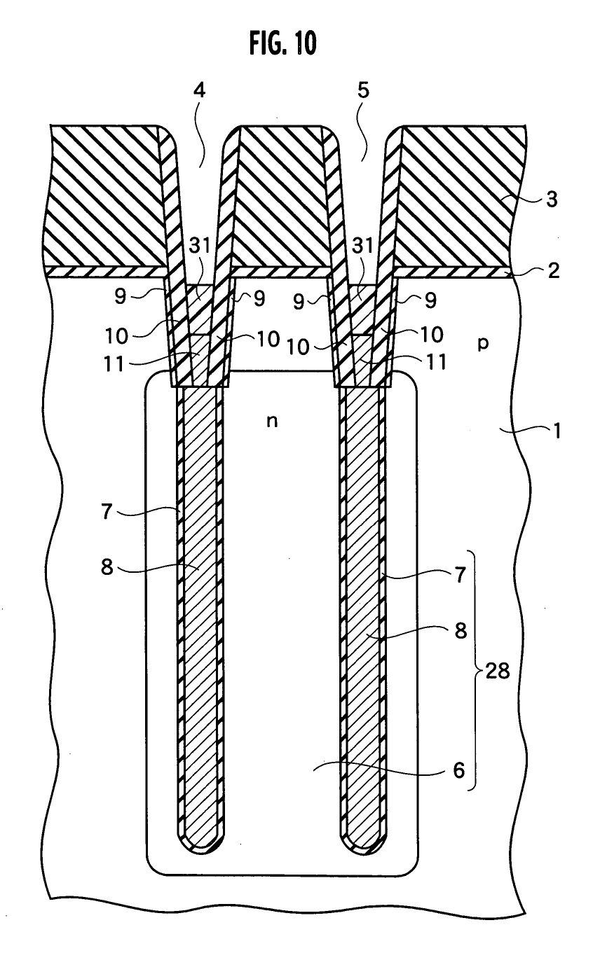

Next, a phosphorous-doped amorphous silicon film is deposited through CVD. The amorphous silicon portions 11 are embedded in the trenches 4 and 5. The amorphous silicon portions 11 are etched back to an appropriate depth of 200 nm or more, for example, which is deeper than that in the first embodiment. A resist is applied so as to embed resist portions 31 in the trenches 4 and 5. As shown in FIG. 10, the resist portions 31 are etched back to an appropriate depth of 130 nm or more, for example.

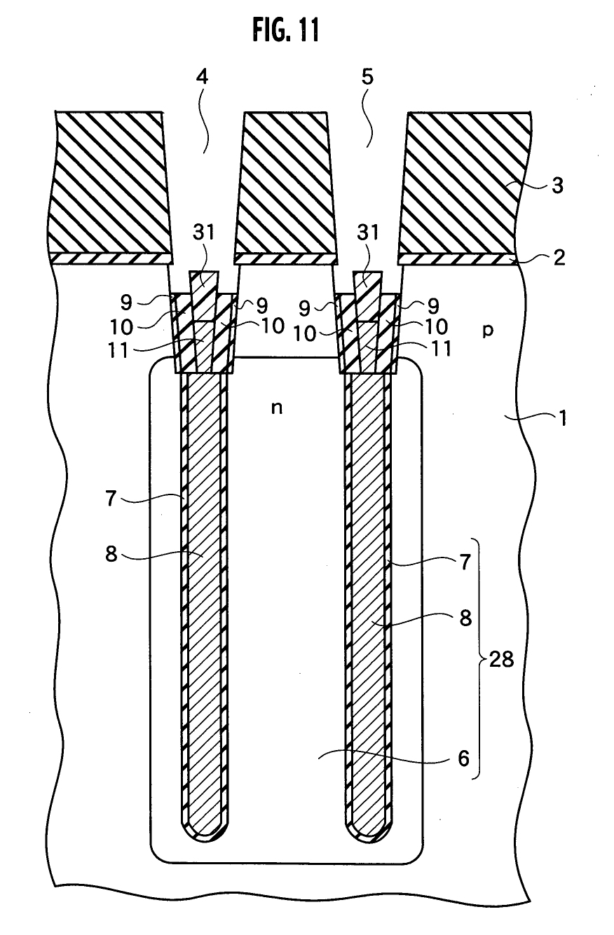

As shown in FIG. 11, the thick collar oxide films 9 and 10 are removed through wet etching using the resist portions 31 as a mask. The resist portions 31 are removed. This operation makes the tops of the thick collar oxide films 9 and 10 higher than the surfaces of the amorphous silicon portions 11. In addition, when depositing the thin collar oxide films 12, or when depositing the storage nodes 14, voids are not generated between the thin collar oxide films 12 and the silicon oxide films 13.

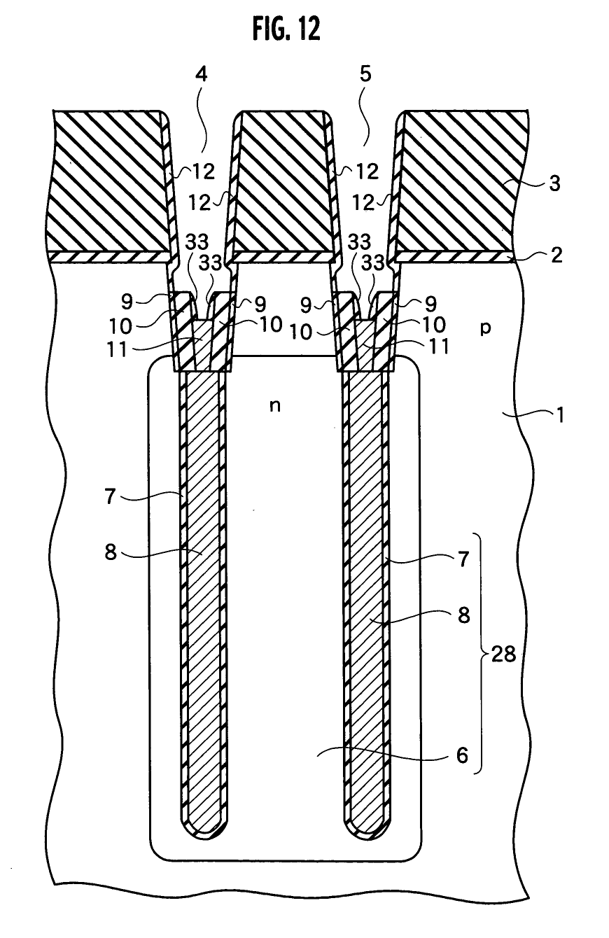

Next, thin collar oxide films 12 with a thickness of 15 nm, for example, are deposited on the sides of the trenches 4 and 5 through CVD. As shown in FIG. 12, the collar oxide films 12 are removed only on the bottom of the trenches 4 and 5 using dry etching techniques. At this time, the sidewall oxide films 33 are formed upon the amorphous silicon portions 11 on the sides of the thick collar oxide films 9 and 10.

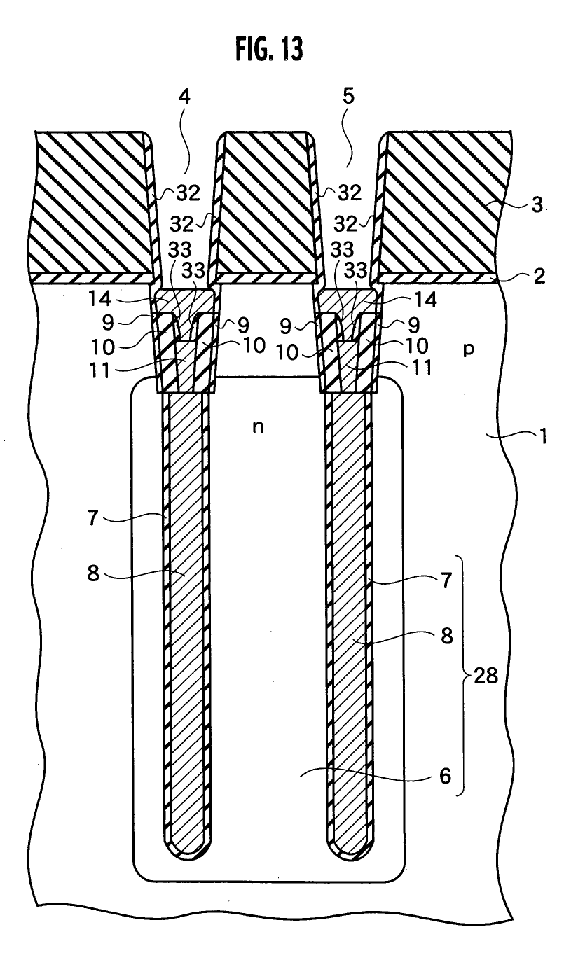

Amorphous silicon films are deposited so as to embed the storage nodes 14 in the trenches 4 and 5. As shown in FIG. 13, the storage nodes 14 are etched back to a predetermined depth.

As with the first embodiment, the STI and the TTO 24 are formed, the select transistors 16 through 21, the gate interconnects 22, and the sidewalls 23 are formed, and the conductor portions 15 are then formed.

As described above, according to the second embodiment, a semiconductor memory, which allows narrow intervals between select transistors without increasing the resistance between surface strap contacts, can be provided. Further according to the second embodiment, a fabrication method for the semiconductor memory, which allows narrow intervals between select transistors without increasing the resistance between surface strap contacts, can be provided.

### THIRD EMBODIMENT

A semiconductor memory according to a third embodiment of the present invention has the same structure as the semiconductor memory of the second embodiment in FIG. 9. This allows the same effectiveness as with the first and the second embodiment.

A semiconductor memory fabrication method of the third embodiment is described. The semiconductor memory fabrication method according to the third embodiment is the same as the semiconductor memory fabrication method according to the first embodiment up until removal of the deposited silicon oxide films 10 only on the bottom of the trenches 4 and 5 of FIG. 5.

Next, a phosphorous-doped amorphous silicon film is deposited through CVD. The amorphous silicon portions 11 are embedded in the trenches 4 and 5. The amorphous silicon portions 11 are etched back to an appropriate depth of 100 nm or more, for example, which is shallower than that in the first embodiment.

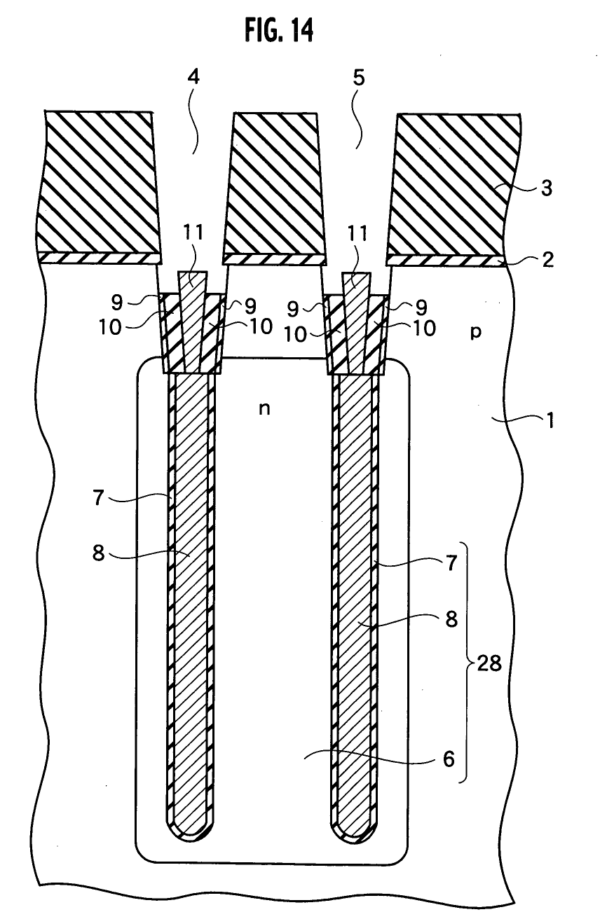

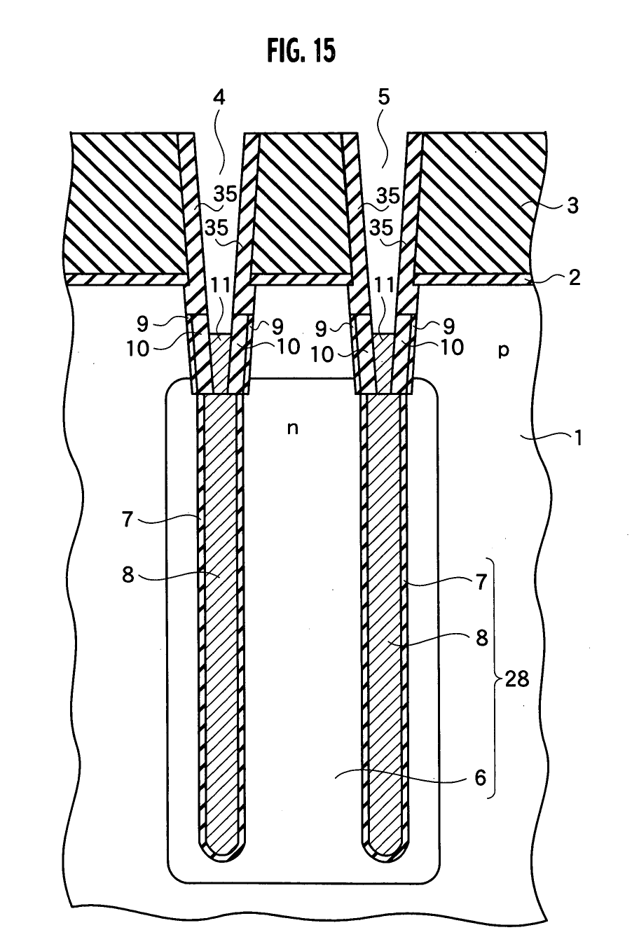

As shown in FIG. 14, the thick collar silicon oxide films 9 and 10 are removed through wet etching using the amorphous silicon portions 11 as a mask. Next, a boron silicate glass (BSG) film 35 is deposited. The thickness of the BSG film 35 is set to 30 nm, for example, which is approximately the same or thicker than that of the thick collar oxide films 9 and 10. The BSG films 35 only on the bottom of the trenches 4 and 5 are removed using dry etching techniques. As shown in FIG. 15, the amorphous silicon portions 11 are once again etched back to an appropriate depth of 150 nm or more, for example, using the BSG films 35 and the thick collar oxide films 9 and 10 as masks. The BSG films 35 are selectively etched through VPC relative to the silicon substrate 1, the amorphous silicon portions 11, and the collar oxide films 9 and 10, completely removing the BSG films 35. This makes the surfaces of the amorphous silicon portions 11 lower in height than the tops of the thick collar oxide films 9 and 10. The remainder of the method is the same as with the fabrication method of the second embodiment. The remainder of the fabrication method of the third embodiment uses the steps after deposition of the thin collar oxide films 12 of the second embodiment. In addition, as with the second embodiment, when depositing the thin collar oxide films 12, or when depositing the storage nodes 14, voids are not generated between the thin collar oxide films 12 and the silicon oxide films 13.

As described above, according to the third embodiment, a semiconductor memory, which allows narrow intervals between select transistors without increasing the resistance between surface strap contacts, can be provided. Further according to the third embodiment, a fabrication method for the semiconductor memory, which allows narrow intervals between select transistors without increasing the resistance between surface strap contacts, can be provided.

### FOURTH EMBODIMENT

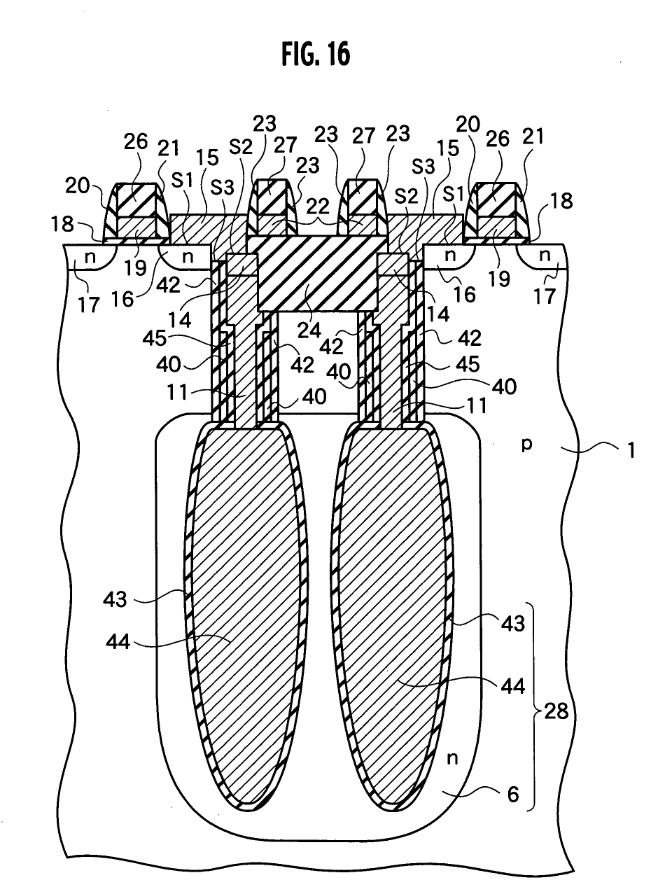

A semiconductor memory according to a fourth embodiment of the present invention, as shown in FIG. 16, includes a semiconductor substrate 1, capacitors 28, collar oxide films 42 and 40, storage nodes 14, select transistors 16 through 21 and 26, conductor portions 15, amorphous silicon portions 11, a shallow trench isolation (STI) 24, gate interconnects 22, cap insulator films 27, and sidewalls 23.

The semiconductor substrate 1 includes trenches. The width of the trenches at the capacitors 28 is wider than at the collar oxide films 42 and 40. The capacitors 28 are arranged in the lower portions of the trenches. The capacitors 28 include storage electrodes 44, a plate electrode 6, and capacitor dielectric films 43. The storage electrodes 44 are arranged in the lower portions of the trenches. The plate electrode 6 is arranged in the semiconductor substrate 1 including the trench surfaces. The capacitor dielectric films 43 are arranged between the plate electrode 6 and the storage electrodes 8 on the trench sides.

The collar oxide films 42 and 40 are arranged on the trench sides upon the capacitors 28. The collar oxide films 40 and 42 have an upper collar member and a lower collar member. The collar oxide films 40 and 42 have a height difference so that an upper film thickness W3 of the upper collar member is thinner than a lower film thickness W4 of the lower collar member. The collar oxide film 40 is called a front silicon oxide film. The collar oxide film 42 is called a back silicon oxide film. The back silicon oxide films 42 are arranged on the trench sides upon the capacitors 28. The thickness of the back silicon oxide films 42 is equivalent to the upper film thickness of the collar oxide films 42 and 40. The front silicon oxide films 40 are arranged on the sides of the back silicon oxide films 42 upon the capacitors 28. The thickness of the front silicon oxide films 40 is equivalent to the difference between the lower film thickness and the upper film thickness of the collar oxide films 42 and 40.

A dielectric film 45 is provided on the surface of the front silicon oxide films 40 and the back silicon oxide films 42, respectively. The dielectric film 45 and the capacitor dielectric film 43 are formed of a single piece of material; therefore there is no interface therebetween. The amorphous silicon portions 11 and the storage nodes 14 are provided on the surfaces of the dielectric films 45.

The storage nodes 14 are arranged in the upper portions of the trenches at sides of the collar oxide films 40 and 42. The storage nodes 14 are electrically connected to the storage electrodes 44 via the amorphous silicon portions 11.

The select transistor includes doped layers 16 and 17, a gate insulator film 18, a gate electrode 19, a cap insulator film 26, and sidewalls 20 and 21. The doped layers 16 are provided on the surface of the semiconductor substrate 1, and are in contact with the collar oxide films 10 and 12. The doped layers 17 are provided on the surface of the semiconductor substrate 1, and separated from the doped layers 16. The gate insulator films 18 are provided upon the doped layers 16 and 17 on the semiconductor substrate 1. The gate electrodes 19 are arranged upon the gate insulator films 18. The cap insulator films 26 are arranged upon the gate electrodes 19. The sidewalls 20 and 21 are arranged on a side of the gate electrodes 19 on the gate insulator films 18, respectively.

The conductor portions 15 serve as surface strap contacts. The conductor portions 15 are arranged upon opposing doped layers 16 and storage nodes 14 via the back silicon oxide films 42 and the dielectric films 45.

The amorphous silicon portions 11 are arranged in the trenches on the surface of the dielectric films 45. The amorphous silicon portions 11 provide a conduction connection between the storage electrodes 44 and the storage nodes 14 into conduction. The amorphous silicon portion 11, the storage electrode 44, and the storage node 14 are formed of a single piece of material; therefore there is no interface between the amorphous silicon portion 11 and the storage electrode 44, and between the amorphous silicon portion 11 and the storage node 14.

The STI 24 is arranged in the periphery of the doped layers 16 and 17 of the select transistors 16 through 21. The STI 24 is arranged on the trenches. The gate electrodes 22 are arranged upon the STI 24. The sidewalls 23 are arranged on the sides of the gate interconnects 22 upon the STI 24.

In order to prevent a contact area S1 between each doped layer 16 and corresponding conductor portion 15, and a contact area S2 between each storage node 14 and corresponding conductor portion 15 from being reduced as in the first embodiment, a contact area S3 between each conductor portion 15 and corresponding collar oxide films 40 and 42 and dielectric film 43 are narrowed. Specifically, the back silicon oxide films 42 of the collar oxide films 40 and 42 is made thinner.

This structure allows an increase in the contact surface between each storage nodes 14 and corresponding conductor portions 15, and a decrease in the resistance of the interface between each storage node 14 and corresponding conductor portion 15. To the contrary, even if the semiconductor memory is miniaturized, the contact areas between the storage nodes 14 and the conductor portions 15 are not reduced by the thin back silicon oxide films 42. A semiconductor memory fabrication method of the fourth embodiment is described forthwith.

To begin with, a p-type silicon substrate is prepared as the semiconductor substrate 1. A 2 nm-thick pad silicon oxide film (SiO₂) 2 is formed upon the silicon substrate 1 by oxidizing the substrate 1 through thermal oxidation. A 220 nm-thick pad silicon nitride film (Si₃N₄) is deposited upon the pad oxide film 2 through CVD. Trenches 4 and 5 are formed in the silicon substrate 1 using photolithography and dry etching techniques.

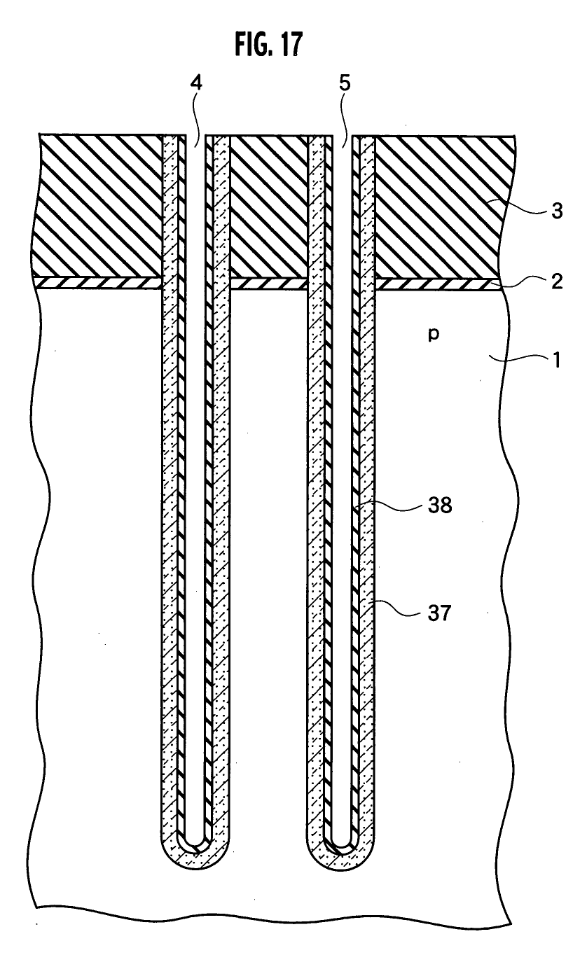

A 30 nm-thick amorphous silicon film 37 is deposited on the sides of the trenches 4 and 5 using CVD techniques. As shown in FIG. 17, a silicon nitride film 38 is deposited on the surface of the amorphous silicon film 37 so as to cover the amorphous silicon portion 37.

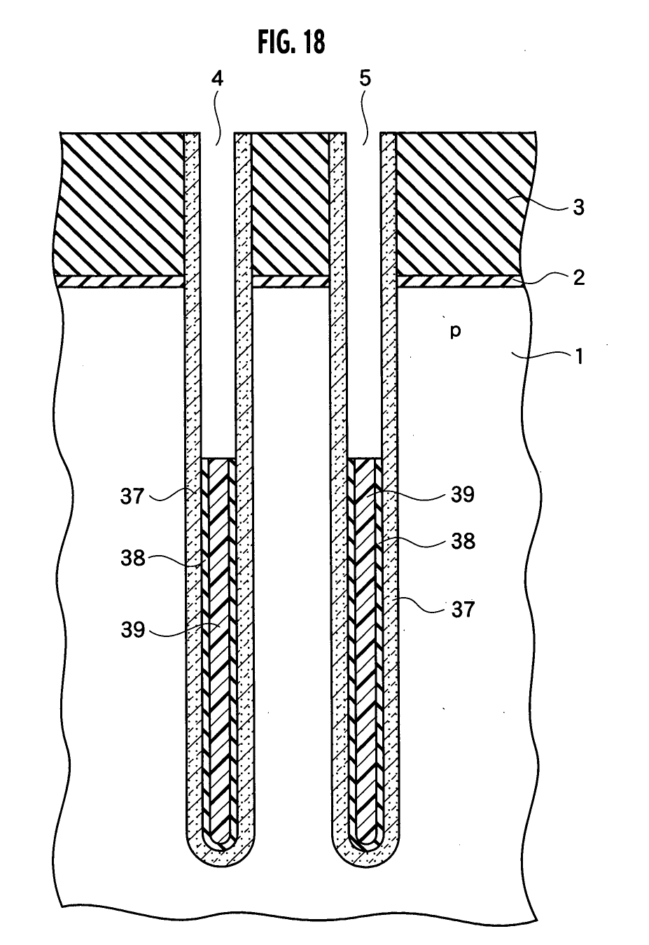

Next, a resist is applied so as to embed resist portions 39 in the lower portions of the trenches 4 and 5. The resist portions 39 are etched back to an appropriate depth of approximately 1″ m, for example. As shown in FIG. 18, the exposed silicon nitride film 38 is removed through wet etching using the resist portions 39 as a mask and the amorphous silicon film 37 as a stopper. The resist portions 39 are removed.

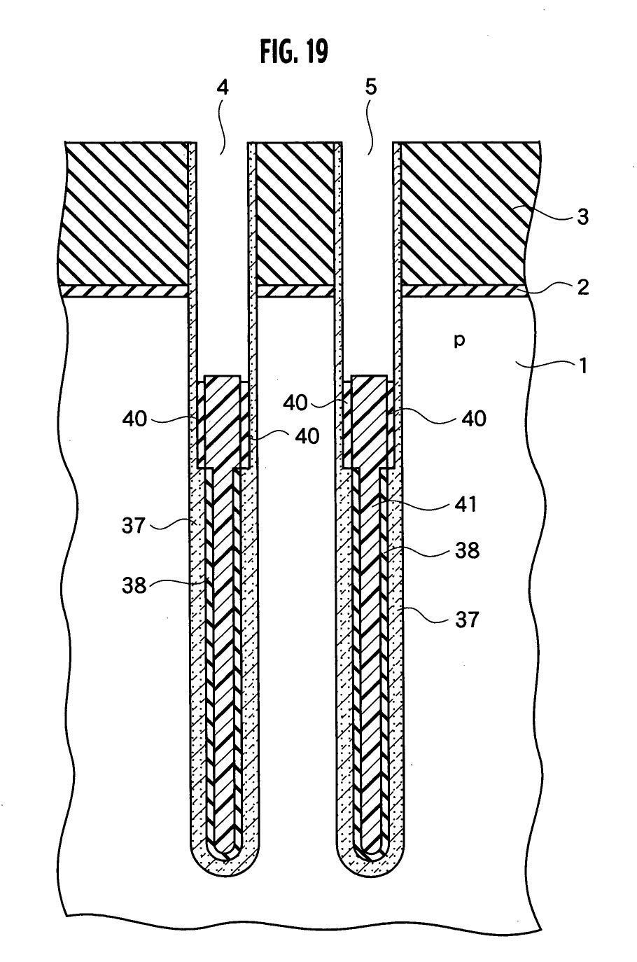

The exposed amorphous silicon film 37 is thermally oxidized to an appropriate depth of approximately 15 nm, for example, forming the front silicon oxide films 40. The thickness of the front silicon oxide films 40 is approximately 15 nm. Once again, a resist is applied so as to embed resist portions 41 in the lower portions of the trenches 4 and 5. The resist portions 41 are etched back to an appropriate depth of approximately 150 nm, for example. As shown in FIG. 19, the exposed front silicon oxide film 40 is removed through wet etching using the resist portions 41 as a mask and the amorphous silicon films 37 as a stopper. The amorphous silicon portions 37 are exposed within the trenches 4 and 5. The resist portions 41 are removed.

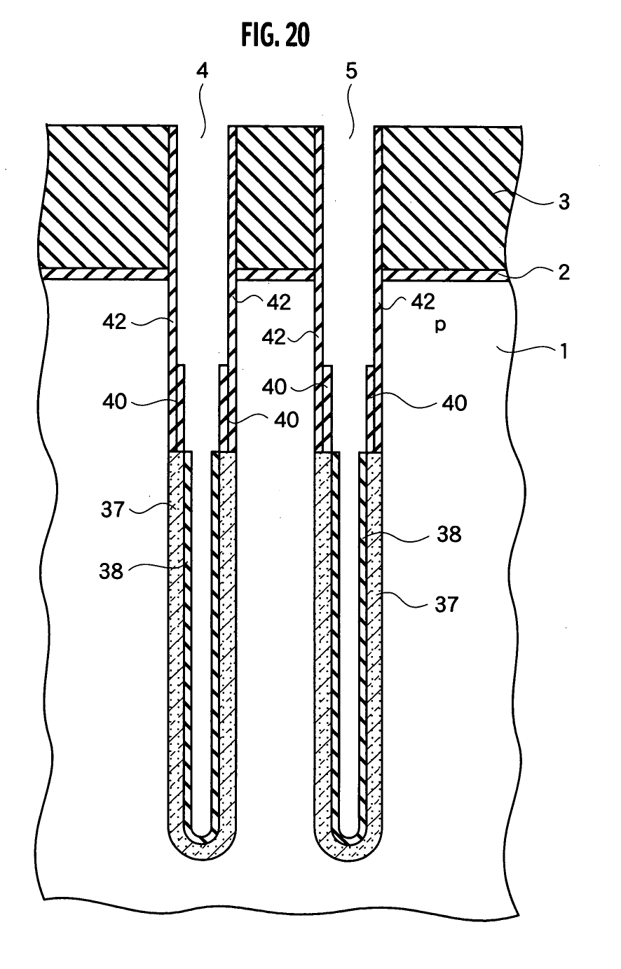

As shown in FIG. 20, the front silicon oxide films 40 on the exposed portions and the surfaces of the amorphous silicon portions 37 are completely thermally oxidized so as to form the back silicon oxide films 42. The thickness of the back silicon oxide films 42 is approximately 15 nm. This process makes the thickness of the upper portions of the collar oxide films 40 and 42 be approximately half the thickness of the lower portions.

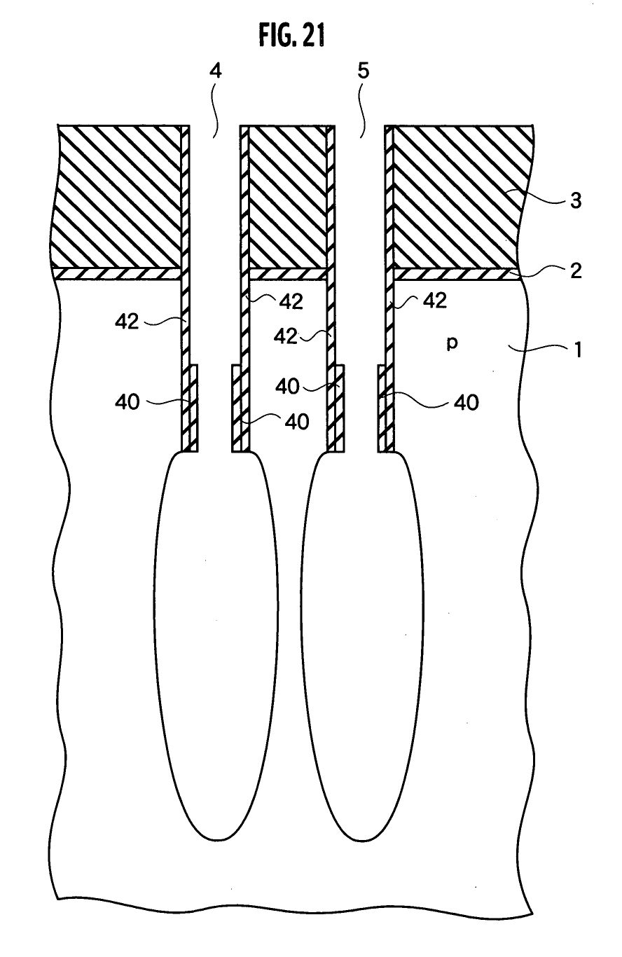

The silicon nitride films 38 are completely removed through wet etching for the collar oxide films 40 and 42 and the amorphous silicon films 37. As shown in FIG. 21, the amorphous silicon portions 37 and the silicon substrate 1 are isotropically etched through chemical dry etching (CDE) or the like using the collar oxide films 40 and 42 as a mask. This process allows an increase in capacity of the trenches 4 and 5, and an increase in surface area of the capacitor dielectric films 43. The capacitance of the capacitors 28 may also be increased.

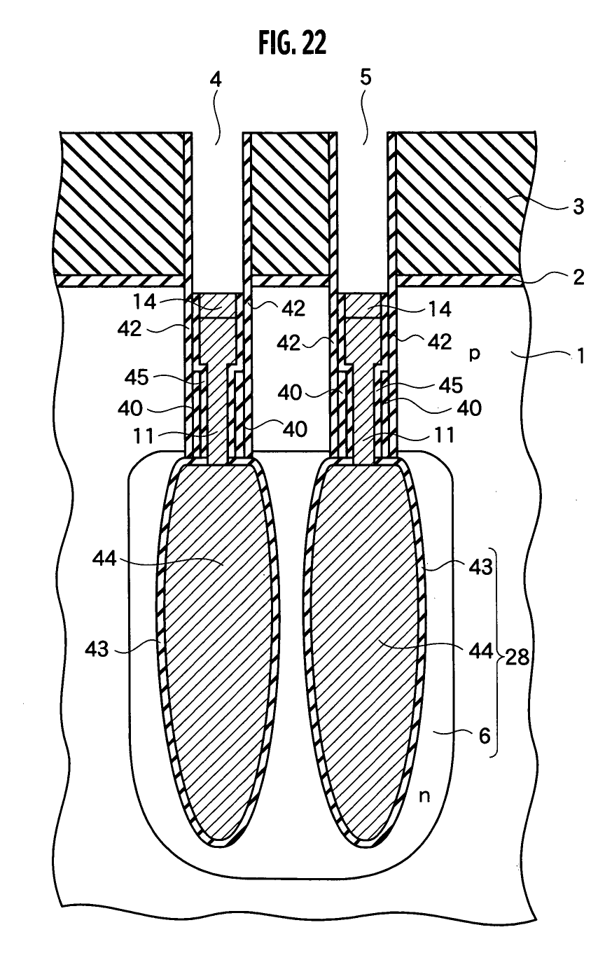

Diffusing and activating an n-type impurity in regions deeper than 1.5″ m in the trenches 4 and 5 forms an embedded plate 6. Next, 2-3 nm-thick capacitor dielectric films 43 and the dielectric films 45 are deposited on the exposed surfaces of the trenches 4 and 5. Since the capacitor dielectric films 43 and the dielectric films 45 are simultaneously deposited, they are formed of a single piece of material and do not have interfaces therebetween. A phosphorous-doped amorphous silicon film is deposited, and the storage electrodes 44, the amorphous silicon portions 11, and the storage nodes 14 are embedded in the trenches 4 and 5. Since the storage electrodes 44, the amorphous silicon portions 11, and the storage nodes 14 are simultaneously embedded, they are formed of a single piece of material and do not have interfaces therebetween. This structure allows a reduction in electrical resistance between the storage electrodes 44 and the storage nodes 14. As shown in FIG. 22, the storage nodes 14 and the dielectric films 45 are etched back to predetermined depths.

As with the first embodiment, the STI and the TTO 24 are formed, the select transistors 16 through 21, the gate interconnects 22, and the sidewalls 23 are formed, and the conductor portions 15 are then formed.

With the fourth embodiment, formation of the collar oxide films 40 and 42 is carried out before formation of the capacitors 28.

As described above, according to the fourth embodiment, a semiconductor memory, which allows narrow intervals between select transistors without increasing the resistance between surface strap contacts, can be provided. Further according to the fourth embodiment, a fabrication method for the semiconductor memory, which allows narrow intervals between select transistors without increasing the resistance between surface strap contacts, can be provided.

The present invention is not limited to the first through fourth embodiments. With the embodiments, the use of the silicon substrate 1 has been described; however, the silicon substrate 1 needs only to be a semiconductor substrate. The semiconductor substrate may be a silicon layer of a silicon on insulator (SOI) substrate, a silicon germanium (SiGe) mixed crystal, a silicon germanium carbide (SiGeC) mixed crystal or the like. In addition, the embodiments of the present invention can be modified and implemented in various ways as long as not deviating from the scope of the present invention.

The present invention may be embodied in other specific forms without departing from the spirit or essential characteristics thereof. The embodiments are therefore to be considered in all respects as illustrative and not restrictive, the scope of the present invention being indicated by the appended claims rather than by the foregoing description, and all changes which come within the meaning and range of equivalency of the claims are therefore intended to be embraced therein.

1. A semiconductor memory comprising:
a semiconductor substrate having a trench;
a capacitor having a storage electrode and arranged in a lower portion of the trench;
a collar oxide film arranged on a side of the trench above the capacitor and having an upper collar member and a lower collar member, the upper collar member being thinner than a thickness of the lower collar member so as to provide a height difference therebetween;
a storage node arranged on a side of the collar oxide film in an upper portion of the trench and electrically connected to the storage electrode;
a select transistor provided on a surface of the semiconductor substrate and having a doped layer in contact with the collar oxide film; and
a conductor portion arranged upon the storage node and the doped layer opposing each other via the collar oxide film.

2. The semiconductor memory of claim 1, wherein the collar oxide film comprises:
a thick collar oxide film with a thickness equivalent to the lower collar member, arranged on the side of the trench above the capacitor; and
a thin collar oxide film with a thickness equivalent to the upper collar member, arranged on the side of the trench above the thick collar oxide film.

3. The semiconductor memory of claim 2, further comprising:
an amorphous silicon portion providing an electrical connection between the storage electrode and the storage node and arranged in the trench on the surface of the thick collar oxide film.

4. The semiconductor memory of claim 2, wherein the top of the thick collar oxide film is higher than that of the amorphous silicon portion.

5. The semiconductor memory of claim 2, further comprising a sidewall oxide film arranged upon the amorphous silicon portion on a side of the thick collar oxide film.

6. The semiconductor memory of claim 1, wherein the collar oxide film comprises:
a back silicon oxide film with a thickness equivalent to the upper collar member, arranged on the side of the trench above the capacitor; and
a front silicon oxide film with a thickness equivalent to the difference between the lower and upper collar members, arranged on the side of the back silicon oxide film above the capacitor.

7. The semiconductor memory of claim 1, wherein the capacitor comprises:
a plate electrode arranged in the semiconductor substrate including the surface of the trench; and
a capacitor dielectric film arranged between the plate electrode and the storage electrode on the side of the trench.

8. The semiconductor memory of claim 1, wherein the storage electrode, the storage node, and the amorphous silicon portion are formed of a single piece of material.

9. The semiconductor memory of claim 1, wherein a diameter of the trench at the capacitor is wider than at the collar oxide film.

10. A method of fabricating a semiconductor memory comprising:
forming a trench in a semiconductor substrate;
forming a capacitor having a storage electrode, in a lower portion of the trench;
forming a collar oxide film having an upper collar member and a lower collar member, the upper collar member being thinner than a thickness of the lower collar member so as to provide a height difference therebetween, on a side of the trench;
forming a storage node, which is electrically connected to the storage electrode, on a side of the collar oxide film in an upper portion of the trench;
forming a select transistor having a doped layer in contact with the collar oxide film and provided on a surface of the semiconductor substrate; and
forming a conductor portion arranged upon the storage node and the doped layer opposing each other via the collar oxide film.

11. The method of claim 10, wherein forming the collar oxide film comprises:
forming a thick collar oxide film with a thickness equivalent to the lower collar member on the side of the trench; and
forming a thin collar oxide film with a thickness equivalent to the upper collar member on the side of the trench on the thick collar oxide film.

12. The method of claim 11, wherein forming the thin collar oxide film comprises:
forming an amorphous silicon portion in the trench on a surface of the thick collar oxide film; and
etching the thick collar oxide film using the amorphous silicon portion as a mask.

13. The method of claim 11, wherein forming the thin collar oxide film comprises:
forming an amorphous silicon portion in the trench on the surface of the thick collar oxide film;
forming a resist portion in the trench on a surface of the thick collar oxide film above the amorphous silicon portion: and
etching the thick collar oxide film using the amorphous silicon portion and the resist portion as a mask.

14. The method of claim 11, wherein forming the thin collar oxide film comprises:
forming an amorphous silicon portion in the trench on a surface of the thick collar oxide film;
etching the thick collar oxide film using the amorphous silicon portion as a mask;
forming a boron silicate glass film on the side of the trench above the thick collar oxide film;
etching the top of the amorphous silicon portion until exposing the surface of the thick collar oxide film using the boron silicate glass films as a mask; and
etching the boron silicate glass film.

15. The method of claim 10, wherein forming the collar oxide films comprises:
forming an amorphous silicon portion on the side of the trench;
oxidizing the surface of the amorphous silicon film to form a front silicon oxide film;
etching an upper portion of the front silicon oxide film; and
oxidizing the underside of the amorphous silicon film, forming a back silicon oxide film.

16. The method of claim 15, wherein forming the collar oxide film further comprises:
forming a silicon nitride film on the surface of the amorphous silicon portion;
forming a resist portion on the surface of the silicon nitride film from the bottom of the trench to a specific depth at which the capacitor is to be formed; and
etching the silicon nitride film using the resist portion as a mask.

17. The method of claim 10, wherein said forming the collar oxide film is carried out before formation of the capacitor.

18. The semiconductor memory of claim 10, wherein forming the capacitor comprises:
forming a plate electrode in the semiconductor substrate including the surface of the trench; and
forming a capacitor dielectric film and the storage electrode in the trench.

19. The method of claim 10, wherein forming the capacitor comprises:
increasing the volume of the lower portion of the trench.
